(19) United States
(12) Patent Application Publication
(10) Pub. No.: US 2019/0189853 A1
(43) Pub. Date: Jun. 20, 2019

(54) LIGHT EMITTING DEVICE PACKAGE

(71) Applicant: Samsung Electronics Co., Ltd., Suwon-si (KR)

(72) Inventors: Hanul YOO, Bucheon-si (KR); Sung Hyun SIM, Uiwang-si (KR); Ji Hye YEON, Suwon-si (KR); Yong Il KIM, Seoul (KR); Dong Gun LEE, Hwaseong-si (KR)

(21) Appl. No.: 16/011,903

(22) Filed: Jun. 19, 2018

(30) Foreign Application Priority Data
Dec. 19, 2017 (KR) 10-2017-0175436

(51) Int. Cl. H01L 33/38; H01L 33/40; H01L 33/46

(52) U.S. Cl. CPC H01L 33/385; H01L 33/40; H01L 33/504; H01L 2933/0016; H01L 2933/005; H01L 33/46

(57) ABSTRACT

A light emitting device package comprises a light emitting cell array including a first light emitting cell, a second light emitting cell, and a third light emitting cell, and including a first surface, and a second surface, disposed to oppose the first surface; a plurality of metal pillars disposed on the first surface of the light emitting cell array and electrically connected to the first light emitting cell, the second light emitting cell, and the third light emitting cell; and a molding portion encapsulating the light emitting cell array and the plurality of metal pillars, wherein the plurality of metal pillars include a conductive layer and a bonding layer disposed below the conductive layer, and an interface between the bonding layer and the conductive layer is higher than a lower surface of the molding portion.

### CROSS-REFERENCE TO RELATED APPLICATION

This application claims the benefit of priority under 35 U.S.C. § 119 to Korean Patent Application No. 10-2017-0175436, filed on Dec. 19, 2017, in the Korean Intellectual Property Office, the disclosure of which is incorporated herein by reference in its entirety.

### BACKGROUND

### 1. FIELD

This disclosure relates to light emitting device packages.

### 2. DESCRIPTION OF RELATED ART

Light emitting devices, such as semiconductor light emitting diodes (LEDs), have not only been used as light sources in lighting devices, but also as light sources in various electronic products. In particular, semiconductor LEDs have commonly been used as light sources for the display panels of various devices and home appliances, such as TVs, mobile phones, PCs, laptop computers, and personal digital assistants (PDAs).

Display devices of the related art contain display panels mainly including a liquid crystal display (LCD) and a backlight. Recently, however, display devices have been developed that do not have separate backlights and use LED devices as individual pixels. Such display devices may not only be compact, but may also implement a relatively high luminance display device having greater light efficiency, as compared to an LCD display of the related art. In addition, since the aspect ratio of a display screen may be freely changed and may be implemented to have a large area, such display devices may be provided as various types of large displays.

### SUMMARY

Certain disclosed embodiment provide a chip-scale light emitting device package allowing for ease in a surface mounting process and implementing full color light.

In some embodiments, the disclosure is directed to a light emitting device package, comprising: a light emitting cell array having a first surface and a second surface that is opposite to the first surface, the light emitting cell array including a first light emitting cell, a second light emitting cell, and a third light emitting cell, wherein each of the first light emitting cell, the second light emitting cell, and the third light emitting cell has a first conductivity-type semiconductor layer, an active layer, and a second conductivity-type semiconductor layer; a plurality of metal pillars disposed on the first surface of the light emitting cell array and electrically connected to the first light emitting cell, the second light emitting cell, and the third light emitting cell; and a molding portion encapsulating the light emitting cell array and the plurality of metal pillars, wherein each of the plurality of metal pillars includes a conductive layer and a bonding layer, the conductive layer being disposed between the light emitting cell array and the bonding layer, and wherein an interface between the bonding layer and the conductive layer is at a higher vertical level than a lower surface of the molding portion.

In some embodiments, the disclosure is directed to a light emitting device package, comprising: a light emitting cell array having a first surface and a second surface opposite the first surface, the light emitting cell array including a plurality of light emitting cells; a plurality of metal pillars disposed on the first surface of the light emitting cell array and electrically connected to the plurality of light emitting cells, one of the plurality of metal pillars being electrically connected in common to the plurality of light emitting cells; and a molding portion encapsulating the light emitting cell array and the plurality of metal pillars, wherein each of the plurality of metal pillars includes at least two layers stacked on one another, each of the at least two layers being comprised of a different material, and wherein a lower surface of the plurality of metal pillars protrudes beyond a lower surface of the molding portion.

In some embodiments, the disclosure is directed to a light emitting device package, comprising: a light emitting cell array having a first surface, and a second surface, disposed opposite the first surface, the light emitting cell array including a first light emitting cell, a second light emitting cell, and a third light emitting cell, each of the first light emitting cell, the second light emitting cell, and the third light emitting cell having a first conductivity-type semiconductor layer, an active layer, and a second conductivity-type semiconductor layer; four metal pillars disposed on the first surface of the light emitting cell array and electrically connected to the first light emitting cell, the second light emitting cell, and the third light emitting cell; a partition structure disposed on the second surface of the light emitting cell array and including a first light emitting window, a second light emitting window, and a third light emitting window, wherein the first light emitting window, the second light emitting window, and the third light emitting window corresponding to the first light emitting cell, the second light emitting cell, and the third light emitting cell, respectively; a first light adjusting portion, a second light adjusting portion, and a third light adjusting portion respectively disposed in the first light emitting window, the second light emitting window, and the third light emitting window and respectively configured to provide red light, blue light, and green light; and a molding portion encapsulating the light emitting cell array and the four metal pillars, wherein lower surfaces of the four metal pillars protrude beyond a lower surface of the molding portion, wherein each of the four metal pillars includes a conductive layer and a bonding layer, the conductive layer and the bonding layer being formed of different materials, and wherein an interface between the bonding layer and the conductive layer is at a higher vertical level than the lower surface of the molding portion.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1 and 2 are a schematic top view and a schematic rear view of a light emitting device package, according to an example embodiment;

FIG. 3 is a cross-sectional view taken along line I-I′ of a light emitting device package illustrated in FIG. 1;

FIG. 4 is a cross-sectional view of a light emitting device package, according to an example embodiment;

FIG. 5 is a cross-sectional view of a light emitting device package, according to an example embodiment;

FIGS. 6 to 16 are schematic views of main processes of manufacturing a light emitting device package of FIGS. 1 to 3; and

FIG. 17 is a schematic perspective view of a display panel including a light emitting device package, according to an example embodiment.

### DETAILED DESCRIPTION

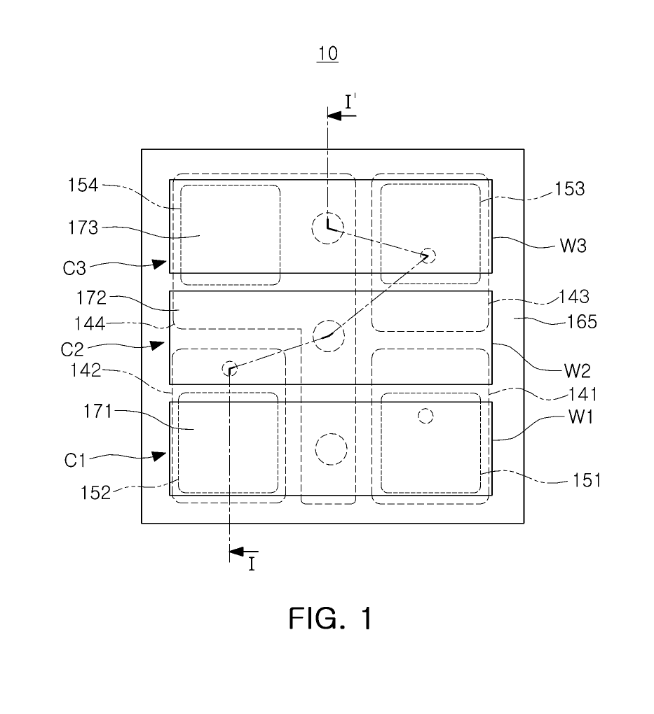

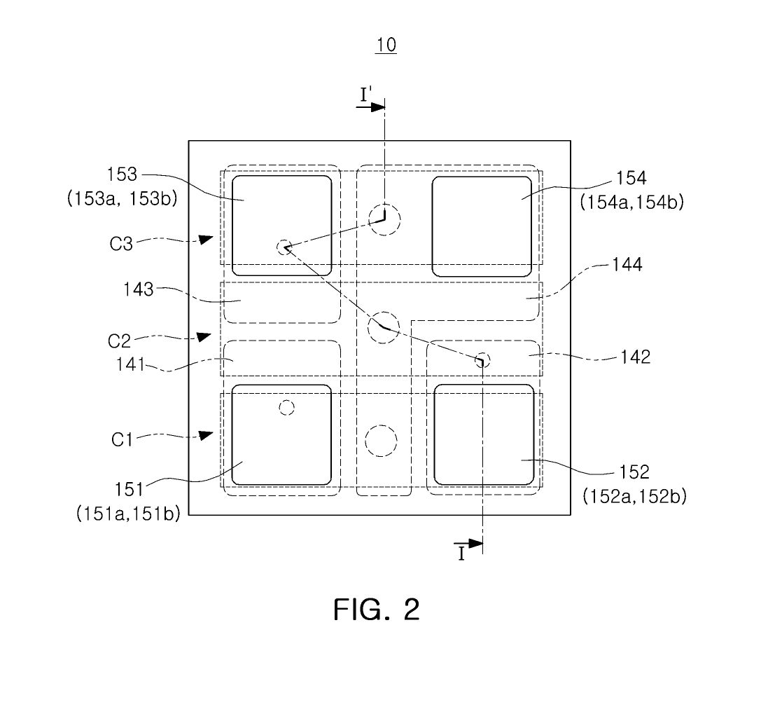

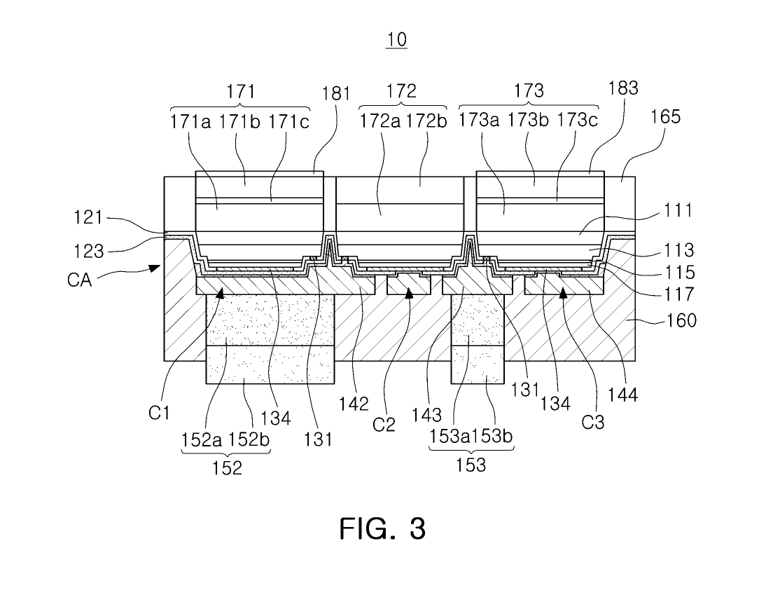

FIGS. 1 and 2 are a schematic top view and a schematic rear view of a light emitting device package according to an example embodiment, while FIG. 3 is a cross-sectional view taken along line I-I′ of a light emitting device package illustrated in FIGS. 1 and 2.

With reference to FIGS. 1 to 3, a light emitting device package 10 according to an example embodiment may include a light emitting cell array CA having a first light emitting cell C1, a second light emitting cell C2, and a third light emitting cell C3; a first light adjusting portion 171, a second light adjusting portion 172, and a third light adjusting portion 173, disposed on an upper surface of the light emitting cell array CA to correspond to the first light emitting cell C1, the second light emitting cell C2, and the third light emitting cell C3, respectively; and a partition structure 165 separating the first light adjusting portion 171, the second light adjusting portion 172, and the third light adjusting portion 173 from one another. The first to fourth metal pillars 151 to 154 may be disposed on a lower surface of the light emitting cell array CA, the lower surface being opposite to the upper surface on which is formed on the partition structure 165.

The first light emitting cell C1, the second light emitting cell C2, and the third light emitting cell C3 may include epitaxial layers, such as a first conductivity-type (e.g., n-type) semiconductor layer 113, an active layer 115, and a second conductivity-type (e.g., p-type) semiconductor layer 117, as illustrated in FIG. 3. The first light emitting cell Cl, the second light emitting cell C2, and the third light emitting cell C3 may include a buffer layer 111 on the first conductivity-type semiconductor layer 113. The active layer 115 of the first light emitting cell C1, the second light emitting cell C2, and the third light emitting cell C3 may be configured to emit the same wavelength of light. For example, the active layer 115 may emit blue light or ultraviolet light.

The light emitting device package 10 may include a first insulating layer 121 and a second insulating layer 123, surrounding the first light emitting cell C1, the second light emitting cell C2, and the third light emitting cell C3. The first insulating layer 121 and the second insulating layer 123 may cover top and side surfaces of the first light emitting cell C1, the second light emitting cell C2, and the third light emitting cell C3 and may allow the first light emitting cell C1, the second light emitting cell C2, and the third light emitting cell C3 to be electrically separated from each other. As illustrated in FIG. 3, a portion of the first insulating layer 121 may be coplanar with upper surfaces of the first light emitting cell C1, the second light emitting cell C2, and the third light emitting cell C3. The first insulating layer 121 may be in contact with the partition structure 165.

The first insulating layer 121 and the second insulating layer 123 may be provided as materials having electrical insulating properties. For example, the first insulating layer 121 and the second insulating layer 123 may be provided as a silicon oxide, a silicon oxynitride, or a silicon nitride. Alternatively, the first insulating layer 121 and the second insulating layer 123 may include a material having reflectivity or a reflective structure. The first insulating layer 121 and the second insulating layer 123 may block mutual optical interference among the first light emitting cell C1, the second light emitting cell C2, and the third light emitting cell C3. The first insulating layer 121 and the second insulating layer 123 may include a distributed Bragg reflector (DBR) structure in which a plurality of insulating layers having different refractive indices are alternately stacked. In the DBR structure, a plurality of insulating layers having different refractive indices may be repeatedly stacked, e.g., stacked from two to 100 times.

The light emitting device package 10 may include an electrode portion disposed on a lower surface of the light emitting cell array CA and electrically connected to the first light emitting cell C1, the second light emitting cell C2, and the third light emitting cell C3. The lower surface of the light emitting cell array CA may be disposed to oppose the upper surface thereof. The electrode portion may be configured to selectively drive the first light emitting cell C1, the second light emitting cell C2, and the third light emitting cell C3. As used herein, items described as being “electrically connected” are configured such that an electrical signal can be passed from one item to the other, and items described as being “electrically isolated” are configured such that electrical signals are prevented from being passed from one item to the other.

The electrode portion may include a first electrode pad 141, a second electrode pad 142, and a third electrode pad 143, connected to the first light emitting cell C1, the second light emitting cell C2, and the third light emitting cell C3, respectively, and may include a fourth electrode pad 144, commonly connected to the first light emitting cell C1, the second light emitting cell C2, and the third light emitting cell C3. The electrode portion may include a first metal pillar 151, a second metal pillar 152, and a third metal pillar 153, connected to the first electrode pad 141, the second electrode pad 142, and the third electrode pad 143, respectively, as well as a fourth metal pillar 154 connected to a fourth electrode pad 144.

For ease of reference, in FIG. 1, the first light emitting cell C1, second light emitting cell C2, and third emitting cell C3 are illustrated with solid lines, the first metal pillar 151, the second metal pillar 152, the third metal pillar 153, and the fourth metal pillar 154 are with shorter dashed lines, and the first electrode pad 141, second electrode pad 142, third electrode pad 143, and fourth electrode pad 144 are illustrated with longer dashed lines. In FIG. 2, the first light emitting cell C1, second light emitting cell C2, and third emitting cell C3 are illustrated with shorter dashed lines, the first metal pillar 151, the second metal pillar 152, the third metal pillar 153, and the fourth metal pillar 154 are with solid lines, and the first electrode pad 141, second electrode pad 142, third electrode pad 143, and fourth electrode pad 144 are illustrated with longer dashed lines.

The first electrode pad 141, the second electrode pad 142, and the third electrode pad 143 may be independently connected to the first conductivity-type semiconductor layer 113 of the first light emitting cell C1, the second light emitting cell C2, and the third light emitting cell C3 through a first electrode 131, respectively. The fourth electrode pad 144 may be commonly connected to the second conductivity-type semiconductor layer 117 of the first light emitting cell C1, the second light emitting cell C2, and the third light emitting cell C3 through a second electrode 134. A form of the fourth electrode pad 144 may be different from those of the first electrode pad 141, the second electrode pad 142, and the third electrode pad 143. For example, when viewed in a plan view, the first electrode pad 141, the second electrode pad 142, and the third electrode pad 143 may have a quadrangular shape. In the case of the rectangular shape, four vertices may have curvature. The fourth electrode pad 144 may overlap the second electrode 134 of the first light emitting cell C1, the second light emitting cell C2, and the third light emitting cell C3, and may have a bent or an L-shaped form. For example, the fourth electrode pad 144 may include a quadrangular pad region and a branch region extended from the quadrangular pad region. The branch region may overlap the first light emitting cell C1, the second light emitting cell C2, and the third light emitting cell C3. The fourth electrode pad 144 may be used as a common terminal of the first light emitting cell C1, the second light emitting cell C2, and the third light emitting cell C3.

A first metal pillar 151 may be electrically connected to the first light emitting cell C1 through the first electrode pad 141 and the first electrode 131; the second metal pillar 152 may be electrically connected to the second light emitting cell C2 through the second electrode pad 142 and the first electrode 131; the third metal pillar 153 may be electrically connected to the third light emitting cell C3 through the third electrode pad 143 and the first electrode 131. The fourth metal pillar 154 may be electrically connected in common to the first light emitting cell C1, the second light emitting cell C2, and the third light emitting cell C3 through the fourth electrode pad 144 and the second electrodes 134. The fourth electrode pad 144 may be used as a common terminal of the first light emitting cell C1, the second light emitting cell C2, and the third light emitting cell C3. The first metal pillar 151 may include a first conductive layer 151a and a first bonding layer 151b disposed below the first conductive layer 151a. The second metal pillar 152 may include a second conductive layer 152a and a second bonding layer 152b disposed below the second conductive layer 152a. The third metal pillar 153 may include a third conductive layer 153a and a third bonding layer 153b disposed below the third conductive layer 153a. The fourth metal pillar 154 may include a fourth conductive layer 154a and a fourth bonding layer 154b disposed below the fourth conductive layer 154a. Thicknesses of the first bonding layer 151b, the second bonding layer 152b, the third bonding layer 153b, and the fourth bonding layer 154b may be less than thicknesses of the first conductive layer 151a, the second conductive layer 152a, the third conductive layer 153a, and the fourth conductive layer 154a. Widths in a horizontal direction of the first bonding layer 151b, the second bonding layer 152b, the third bonding layer 153b, and the fourth bonding layer 154b may be equal to those of the first conductive layer 151a, the second conductive layer 152a, the third conductive layer 153a, and the fourth conductive layer 154a. The first conductive layer 151a, the second conductive layer 152a, the third conductive layer 153a, and the fourth conductive layer 154a may be formed of, for example, copper (Cu). In addition, the first bonding layer 151b, the second bonding layer 152b, the third bonding layer 153b, and the fourth bonding layer 154b may be formed of at least one of silver tin (AgSn) alloy, tin (Sn), and tin silver copper (SnAgCu) alloy.

The light emitting device package 10 may include a molding portion 160 encapsulating the light emitting cell array CA and exposing a portion of the first metal pillar 151, the second metal pillar 152, the third metal pillar 153, and the fourth metal pillar 154. The molding portion 160 may encapsulate the first electrode pad 141, the second electrode pad 142, the third electrode pad 143, and the fourth electrode pad 144, as well as portions of the first metal pillar 151, the second metal pillar 152, the third metal pillar 153, and the fourth metal pillar 154. For example, the molding portion may surround side surfaces of the first conductive layer 151a, the second conductive layer 152a, the third conductive layer 153a, and the fourth conductive layer 154a, and expose side surfaces of the lower portions of the first bonding layer 151b, the second bonding layer 152b, the third bonding layer 153b, and the fourth bonding layer 154b. The molding portion 160 may have a relatively high Young's modulus, in order to firmly support the light emitting device package 10, and provide stability to the light emitting device package 10. In addition, the molding portion 160 may include a material having relatively high thermal conductivity, in order to effectively emit heat from the first light emitting cell C1, the second light emitting cell C2, and the third light emitting cell C3. For example, the molding portion 160 may include an epoxy resin or a silicone resin. In addition, the molding portion 160 may include light reflective particles to reflect light. Titanium dioxide (TiO₂) or aluminum oxide (A1₂O₃) may be used as the light reflective particles, but the disclosure is not limited thereto.

Respective interfaces between the first conductive layer 151a and the first bonding layer 151b, between the second conductive layer 152a and the second bonding layer 152b, between the third conductive layer 153a and the third bonding layer 153b, as well as between the fourth conductive layer 154a and the fourth bonding layer 154b may be higher than a lower surface of the molding portion 160. Lower surfaces of the first bonding layer 151b, the second bonding layer 152b, the third bonding layer 153b, and the fourth bonding layer 154b may be lower than the lower surface of the molding portion 160. For example, the first to fourth conductive layers 151a, 152a, 153a, and 154a are between the respective first to fourth bonding layers 151b, 152b, 153b, and 154b and the first light emitting cell C1, the second light emitting cell C2, and the third light emitting cell C3, and the first to fourth bonding layers 151b, 152b, 153b, and 154b protrude from the molding portion 160. At least a portion of side surfaces of the first bonding layer 151b, the second bonding layer 152b, the third bonding layer 153b, and the fourth bonding layer 154b may be coplanar with side surfaces of the first conductive layer 151a, the second conductive layer 152a, the third conductive layer 153a, and the fourth conductive layer 154a, respectively. The first bonding layer 151b, the second bonding layer 152b, the third bonding layer 153b, and the fourth bonding layer 154b may function as solder bumps when the light emitting device package 10 is mounted on a circuit board.

The partition structure 165 may include a first light emitting window W1, a second light emitting window W2, and a third light emitting window W3 in positions corresponding to the first light emitting cell C1, the second light emitting cell C2, and the third light emitting cell C3, respectively. The first light emitting window W1, the second light emitting window W2, and the third light emitting window W3 may be provided as spaces to form the first light adjusting portion 171, the second light adjusting portion 172, and the third light adjusting portion 173, respectively. The partition structure 165 may perform a light blocking function so that portions of light transmitted through the first light adjusting portion 171, the second light adjusting portion 172, and the third light adjusting portion 173 may not interfere with each other. For example, the partition structure 165 may be formed of single crystal silicon (Si). Alternatively, the partition structure 165 may be formed of a black matrix. As illustrated in FIG. 3, an upper surface of the partition structure 165 may be coplanar with surfaces of the first light adjusting portion 171, the second light adjusting portion 172, and the third light adjusting portion 173.

The first light adjusting portion 171, the second light adjusting portion 172, and the third light adjusting portion 173 may adjust portions of light emitted by the first light emitting cell C1, the second light emitting cell C2, and the third light emitting cell C3 to be converted into light having different colors.

The first light adjusting portion 171, the second light adjusting portion 172, and the third light adjusting portion 173 may be configured to provide red light, blue light, and green light, respectively. Respective upper surfaces of the first light adjusting portion 171, the second light adjusting portion 172, and the third light adjusting portion 173 may be flat.

Each of the first light adjusting portion 171, the second light adjusting portion 172, and the third light adjusting portion 173 may have a multilayer structure. The first light adjusting portion 171 may include a first phosphor layer 171a and a first transparent resin layer 171b. The second light adjusting portion 172 may include a second phosphor layer 172a and a second transparent resin layer 172b. The third light adjusting portion 173 may include a third phosphor layer 173a and a third transparent resin layer 173b. In some embodiments, as illustrated in FIG. 3, the first light adjusting portion 171 may include a first optical filter layer 171c between the first phosphor layer 171a and the first transparent resin layer 171b. The third light adjusting portion 173 may include a third optical filter layer 173c between the third phosphor layer 173a and the third transparent resin layer 173b. Although not illustrated, in certain embodiments, the second light adjusting portion 172 may include a second optical filter layer 172c between the second phosphor layer 171a and the second transparent layer 172b.

The first phosphor layer 171a may be formed of a transparent resin including red phosphors, while the third phosphor layer 173a may be formed of a transparent resin including green phosphors.

The second phosphor layer 172a may be formed of a transparent resin with which a phosphor is not mixed, or may include a blue or cyan phosphor (for example, converting light to have a wavelength within a range of 480 nm to 520 nm) to control color coordinates of blue light. An amount of a phosphor contained in the second phosphor layer 172a may be smaller than that of a phosphor mixed in the first phosphor layer 171a and the third phosphor layer 173a.

The first optical filter layer 171c and the third optical filter layer 173c may selectively block light emitted by the active layer 115.

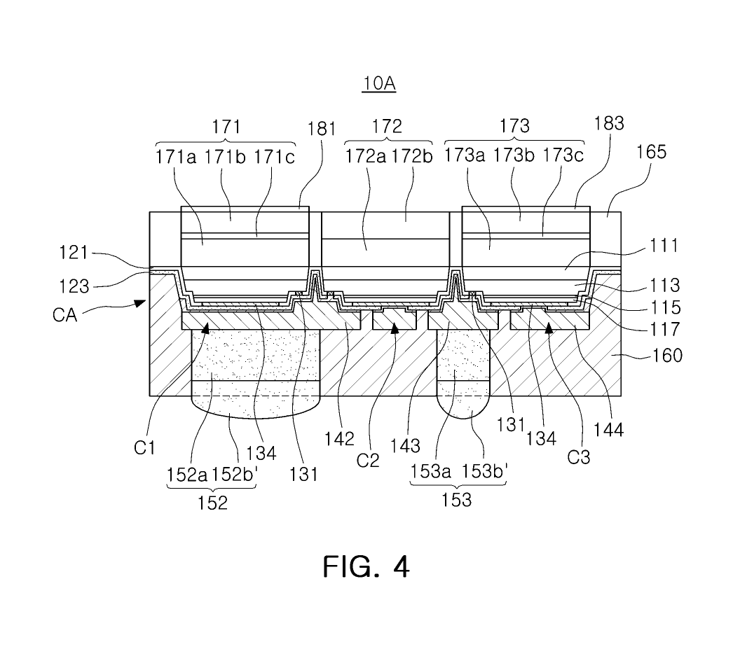

In some embodiments, a first color filter layer 181 and a third color filter layer 183, each individually and selectively transmitting light within a desired wavelength band, may be further disposed on the first light adjusting portion 171 and the third light adjusting portion 173. Only the green light and the red light within the desired wavelength band may be provided using the first color filter layer 181 and the third color filter layer 183, respectively. In addition, although not illustrated in FIG. 3, a resin layer, to prevent deterioration of phosphors, may be further disposed on upper surfaces of the first light adjusting portion 171, the second light adjusting portion 172, and the third light adjusting portion 173. FIG. 4 is a view of a light emitting device package according to an example embodiment.

With reference to the light emitting device package 10A of FIGS. 1, 2, and 4, respective interfaces between a first conductive layer 151a and a first bonding layer 151b′, between a second conductive layer 152a and a second bonding layer 152b′, between a third conductive layer 153a and a third bonding layer 153b′, and between a fourth conductive layer 154a and a fourth bonding layer 154b′ may be higher than a lower surface of a molding portion 160. Each of the first bonding layer 151b′, the second bonding layer 152b′, the third bonding layer 153b′, and the fourth bonding layer 154b′ may include first regions (upper regions) having side surfaces in contact with the molding portion 160 and second regions (lower regions) having a convex curved surface. The second regions may protrude beyond the lower surface of the molding portion 160. A side surface of the second regions of the first bonding layer 151b′, the second bonding layer 152b′, the third bonding layer 153b′, and the fourth bonding layer 154b′ may be coplanar with side surfaces of the first conductive layer 151a, the second conductive layer 152a, the third conductive layer 153a, and the fourth conductive layer 154a, respectively. Widths in a horizontal direction of the first regions of the first bonding layer 151b′, the second bonding layer 152b′, the third bonding layer 153b′, and the fourth bonding layer 154b′ may be equal to widths of the first conductive layer 151a, the second conductive layer 152a, the third conductive layer 153a, and the fourth conductive layer 154a. In an example embodiment, a maximum width in a vertical direction of the second regions may be greater than that of the first regions. The first bonding layer 151b′, the second bonding layer 152b′, the third bonding layer 153b′, and the fourth bonding layer 154b′ may include second regions having a convex curved surface using a reflow process.

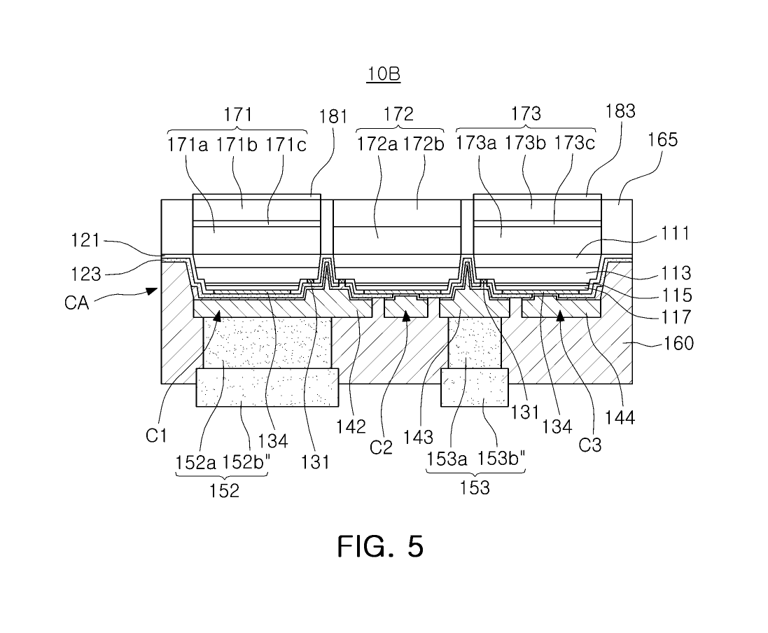

FIG. 5 is a view of a light emitting device package according to an example embodiment.

With reference to the light emitting device package 10B of FIG. 5, respective interfaces between a first conductive layer 151a and a first bonding layer 151b″, between a second conductive layer 152a and a second bonding layer 152b″, between a third conductive layer 153a and a third bonding layer 153b″, and between a fourth conductive layer 154a and a fourth bonding layer 154b″ may be higher than a lower surface of a molding portion 160. Widths in a horizontal direction of the first bonding layer 151b″, the second bonding layer 152b″, the third bonding layer 153b″, and the fourth bonding layer 154b″ may be greater than those of the first conductive layer 151a, the second conductive layer 152a, the third conductive layer 153a, and the fourth conductive layer 154a. In some embodiments, bottom surfaces of each of the first bonding layer 151b″, the second bonding layer 152b″, the third bonding layer 153b″, and the fourth bonding layer 154b″ may be flat and planar, and lower than a bottom surface of the molding portion 160. In another example embodiment, although not illustrated in FIG. 5, lower regions of the first bonding layer 151b″, the second bonding layer 152b″, the third bonding layer 153b″, and the fourth bonding layer 154b″ may have convex curved surfaces in a manner similar to that of FIG. 4.

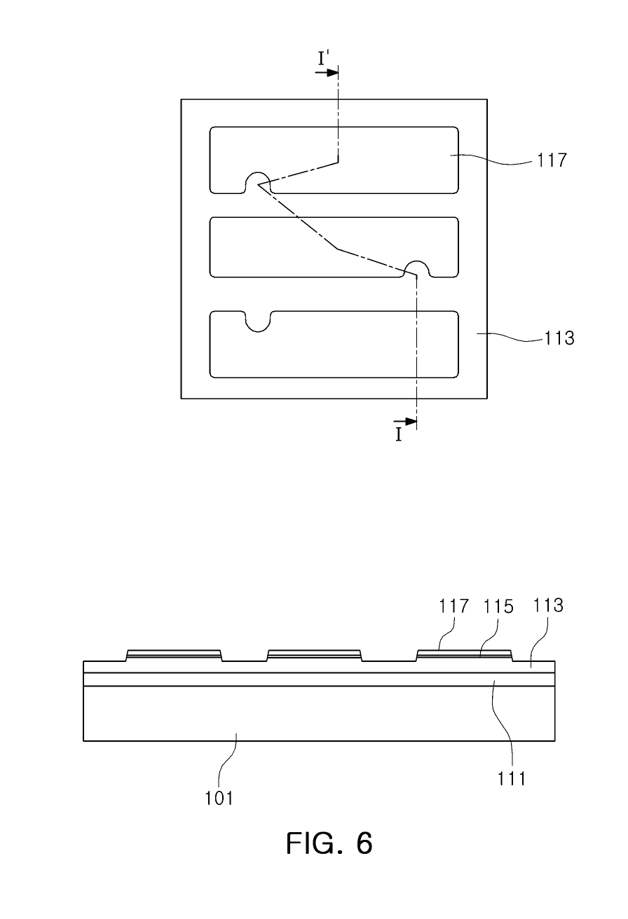

With reference to FIGS. 6 to 17, a method of manufacturing a light emitting device package 10 of an example embodiment will be described. FIGS. 6 to 17 are schematic, cross-sectional views of a main process of manufacturing the light emitting device package 10 illustrated in FIGS. 1 to 3. The method of manufacturing the light emitting device package 10 to be described below with reference to FIGS. 6 to 17 relates to a method of manufacturing a wafer level package. In FIGS. 6 to 17, a region corresponding to a single light emitting device package is illustrated for the sake of convenience.

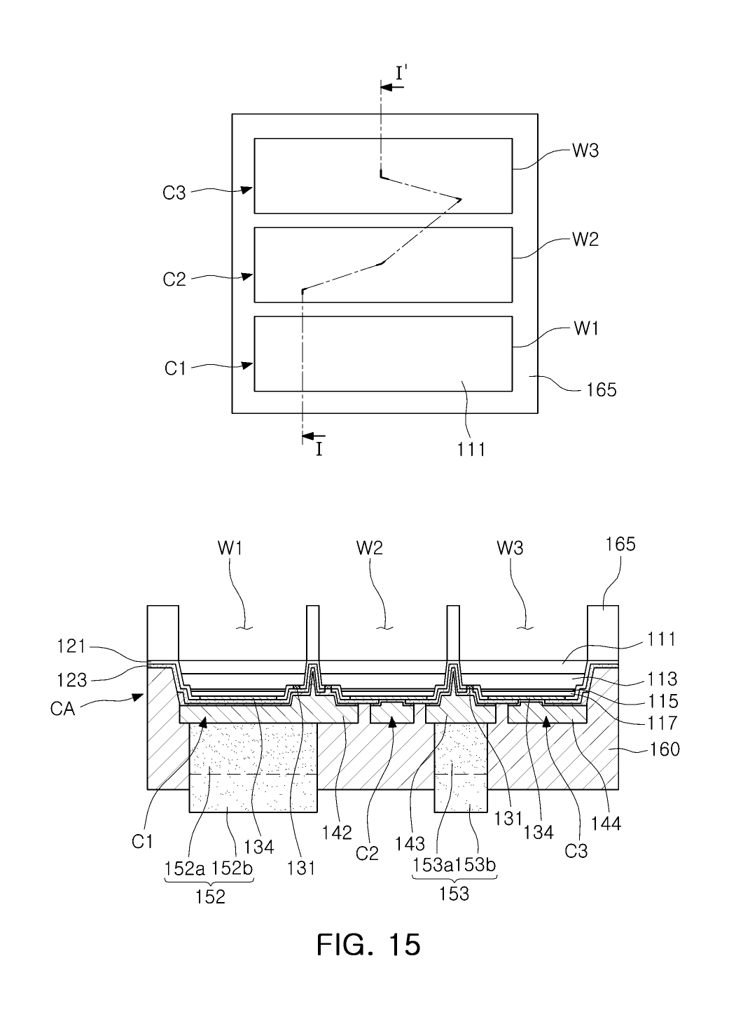

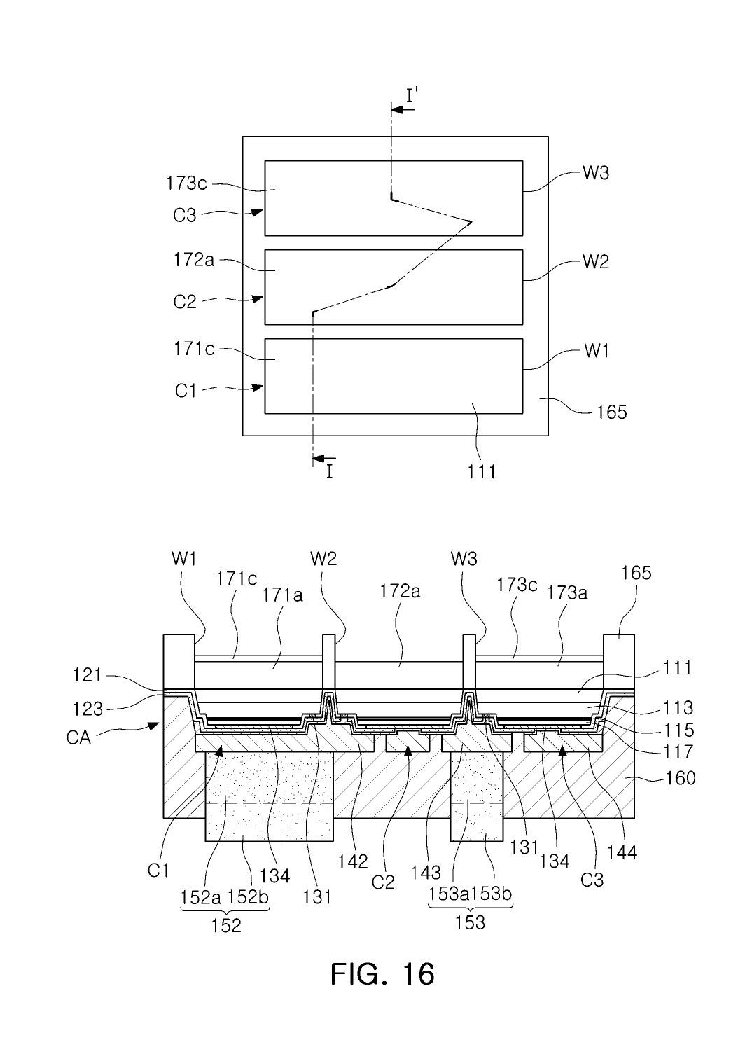

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly. For example, the cross-sectional views of FIGS. 6 to 14 are presented upside down, relative to the cross-sectional views of FIGS. 15 and 16.

With reference to FIG. 6, after a buffer layer 111, a first conductivity-type semiconductor layer 113, an active layer 115, and a second conductivity-type semiconductor layer 117 are sequentially grown on a growth substrate 101, a portion of the second conductivity-type semiconductor layer 117 and the active layer 115 may be removed to form a plurality of mesa structures.

An insulating substrate, a conductive substrate, or a semiconductor substrate may be used as the growth substrate 101, according to some embodiments. For example, the growth substrate 101 may be formed of sapphire, SiC, Si, MgAl₂O₄, MgO, LiAlO₂, LiGaO₂, or GaN.

The buffer layer 111, the first conductivity-type semiconductor layer 113, the active layer 115, and the second conductivity-type semiconductor layer 117 may be provided as epitaxial layers of a group III nitride-based semiconductor layer. The first conductivity-type semiconductor layer 113 may be provided as an n-type nitride semiconductor satisfying InₓAl_{y}Ga_{1-x-y}N (0≤x<1, 0≤y<1, 0≤x+y<1). In addition, an n-type impurity may be provided as Si, germanium (Ge), selenium (Se), tellurium (Te), or the like. The active layer 115 may have a multiple quantum well (MQW) structure in which a quantum well layer and a quantum barrier layer are alternately stacked. For example, the MQW and the quantum barrier layer may be provided as InₓAl_{y}Ga_{1-x-y}N (0≤x<1, 0≤y≤1, 0≤x+y≤1) having different compositions. In a specific example embodiment, the MQW may be provided as InₓGa_{1-x-y}N (0<x≤1), while the quantum barrier layer may be provided as GaN or AlGaN. The second conductivity-type semiconductor layer 117 may be provided as a p-type nitride semiconductor layer satisfying InₓAl_{y}Ga_{1-x-y}N (0≤x<1, 0≤y<1, 0≤x+y<1). In addition, a p-type impurity may be provided as magnesium (Mg), zinc (Zn), beryllium (Be), or the like. The buffer layer 111 may be provided as InₓAl_{y}Ga_{1-x-y}N (0≤x≤1, 0≤y≤1). For example, the buffer layer 111 may be provided as AIN, AlGaN, or InGaN. According to some embodiments, the buffer layer 111 may be formed by combining a plurality of layers having different compositions, or may be formed of a single layer, a composition of which is gradually changed.

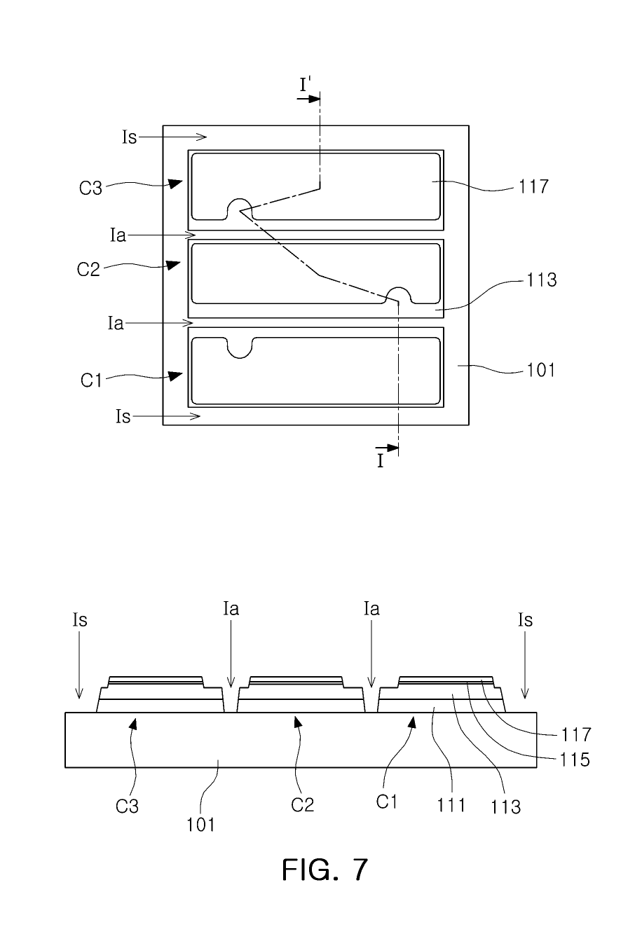

With reference to FIG. 7, an isolation process to separate the plurality of mesa structures may be performed.

The first conductivity-type semiconductor layer 113 and the buffer layer 111 may be etched on a boundary of the plurality of mesa structures, thereby forming an isolation region Is and a sub-isolation region Ia, exposing a portion of a substrate 101. A plurality of light emitting cells C1, C2, and C3 may be formed on the substrate 101 using a process described above. The isolation region Is may be formed in each of three light emitting cells C1, C2, and C3. The isolation region Is may be formed between a first light emitting cell Cl and a third light emitting cell C3. The sub-isolation region Ia may be formed between the first light emitting cell C1 and a second light emitting cell C2, and between the second light emitting cell C2 and the third light emitting cell C3. The first light emitting cell C1, the second light emitting cell C2, and the third light emitting cell C3 may have an inclined side surface with respect to an upper surface of the substrate 101.

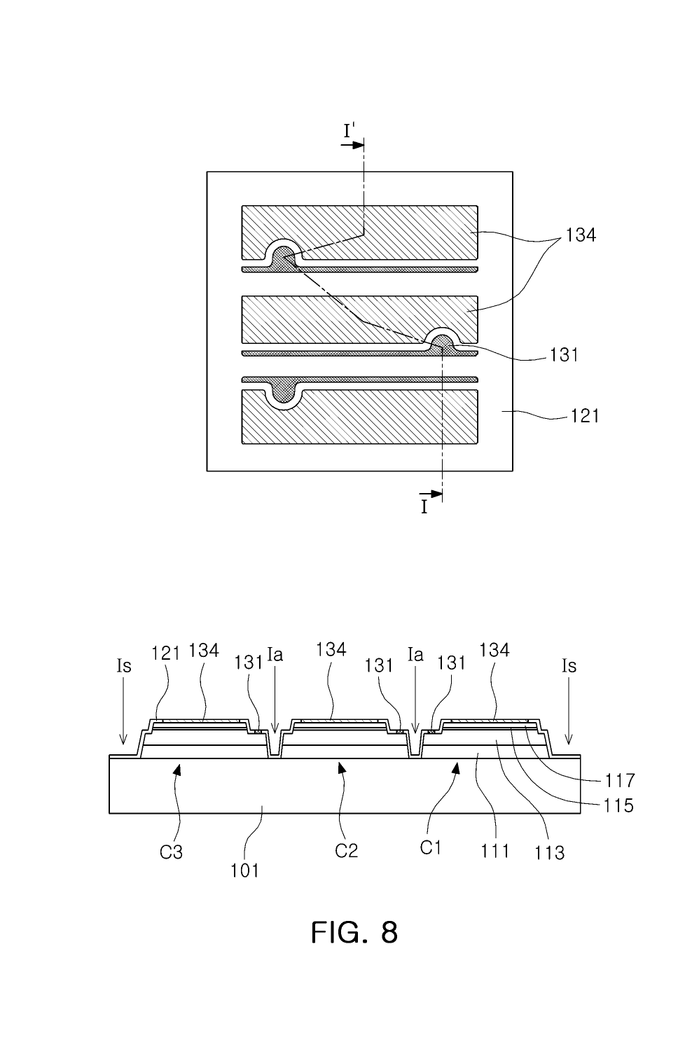

With reference to FIG. 8, a first insulating layer 121 covering the plurality of light emitting cells C1, C2, and C3 may be formed. In addition, a first electrode 131 penetrating through the first insulating layer 121 to be connected to the first conductivity-type semiconductor layer 113, as well as a second electrode 134 penetrating through the first insulating layer 121 to be connected to the second conductivity-type semiconductor layer 117 may be formed.

The first insulating layer 121 may cover side surfaces of the plurality of light emitting cells C1, C2, and C3 of the isolation region Is and the sub-isolation region Ia, and may electrically separate the plurality of light emitting cells C1, C2, and C3. The first insulating layer 121 may have electrical insulating properties, and a material having a relatively low light absorption rate may be used. The first insulating layer 121 may be, for example, a silicon oxide, a silicon oxynitride, a silicon nitride, or combinations thereof. Alternatively, in an example embodiment, the first insulating layer 121 may have a multilayer reflective structure in which a plurality of insulating layers having different refractive indices are alternately stacked. The multilayer reflective structure may be provided as a DBR in which a first insulating layer having a first refractive index and a second insulating layer having a second refractive index are alternately stacked. In the multilayer reflective structure, a plurality of insulating layers having different refractive indices may be repeatedly stacked, e.g., stacked from two to 100 times.

Subsequently, after portions of the first insulating layer 121 are removed, the first electrode 131 and the second electrode 134, formed of a conductive material, may be formed. The portions of the first insulating layer 121 may be removed through, for example, an etch process or another process that provides for selective removal of the first insulating layer 121. The first electrode 133 and the second electrode 134 may be provided as a reflective electrode including silver (Ag), aluminum (Al), nickel (Ni), chrome (Cr), titanium (Ti), copper (Cu), gold (Au), palladium (Pd), platinum (Pt), tin (Sn), tungsten (W), rhodium (Rh), iridium (Ir), ruthenium (Ru), magnesium (Mg), zinc (Zn), and at least one of alloy materials including Ag, Al, Ni, Cr, Ti, Cu, Au, Pd, Pt, Sn, W, Rh, Ir, Ru, Mg, and Zn.

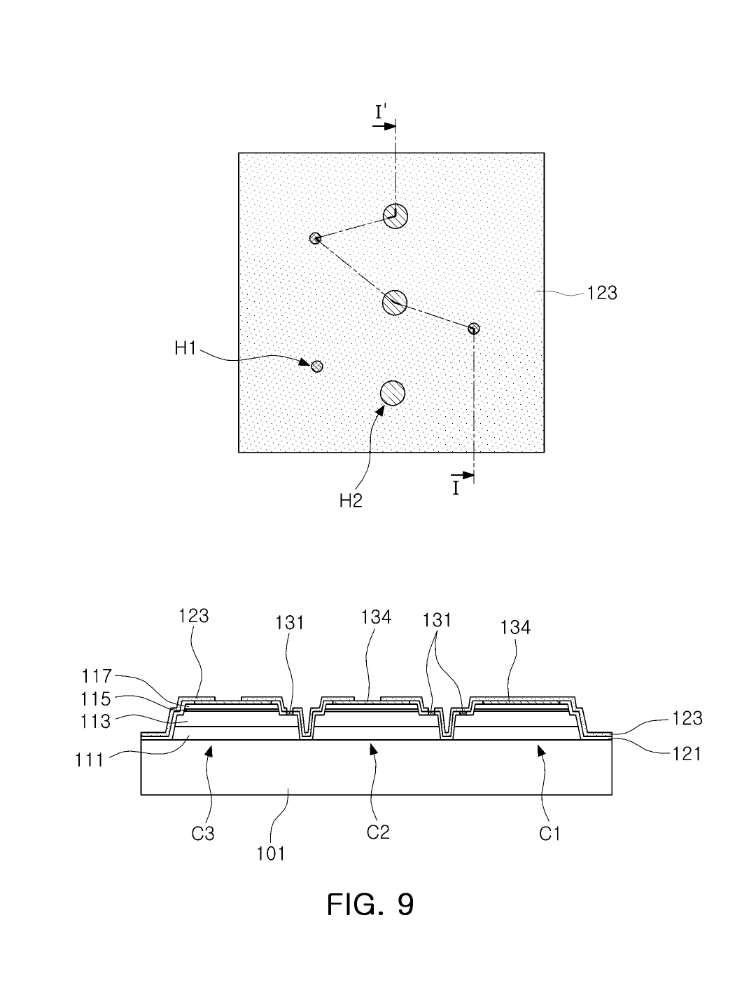

With reference to FIG. 9, a second insulating layer 123 covering the first insulating layer 121, the first electrode 133, and the second electrode 134 may be formed. The second insulating layer 123 may include first contact holes H1 exposing regions of the first electrodes 133 of the plurality of light emitting cells C1, C2, and C3 and second contact holes H2 exposing regions of the second electrode 134. The first contact holes H1 and the second contact holes H2 may be provided by removing portions of the second insulating layer 123 through, for example, an etch process or another process that provides for selective removal of the second insulating layer 123.

The second insulating layer 123 may be formed of a material the same as or similar to that of the first insulating layer 121.

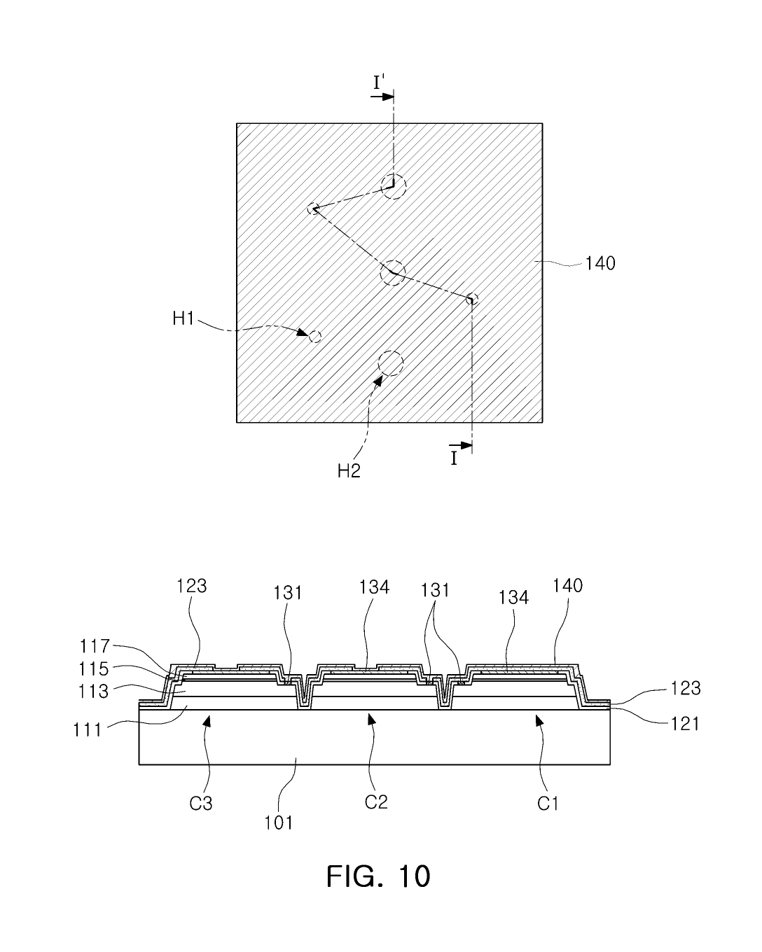

With reference to FIG. 10, a seed metal layer 140 may be formed on a substrate 101. The seed metal layer 140 may cover a surface of a second insulating layer 123 and may be in contact with the first electrode 133 through the first contact holes H1 and the second electrode 134 through the second contact holes H2. The surface of the second insulating layer 123 may be covered in the isolation region Is and the sub-isolation region Ia. The seed metal layer 140 may be formed of, for example, Cu.

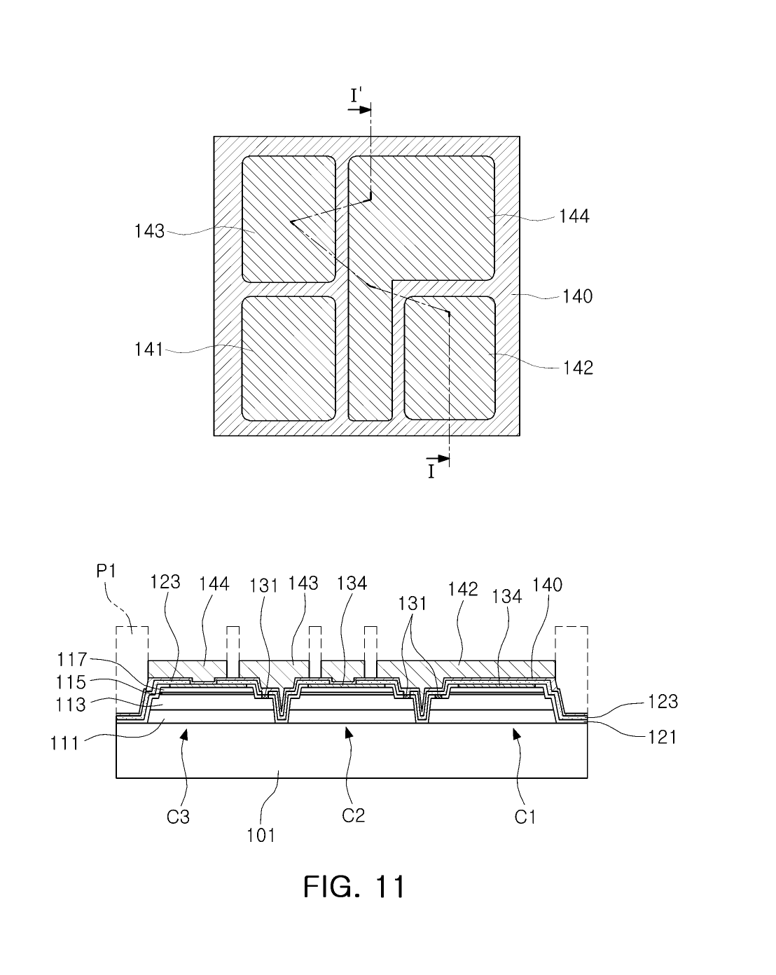

With reference to FIG. 11, a first electrode pad 141, a second electrode pad 142, a third electrode pad 143, and a fourth electrode pad 144 may be formed on the seed metal layer 140.

After a first photoresist pattern P1 is formed, the first electrode pad 141, the second electrode pad 142, the third electrode pad 143, and the fourth electrode pad 144 may be formed using a plating process.

The first electrode pad 141, the second electrode pad 142, the third electrode pad 143, and the fourth electrode pad 144 may be formed of, for example, Cu. The first electrode pad 141, the second electrode pad 142, the third electrode pad 143, and the fourth electrode pad 144 may be formed, for example, to have a thickness of about 10 μm. The first photoresist pattern P1 may be removed after the plating process is completed.

The first electrode pad 141 may overlap the first electrode 131 of the first light emitting cell C1, the second electrode pad 142 may overlap the first electrode 131 of the second light emitting cell C2, and the third electrode pad 143 may overlap the first electrode 131 of the third light emitting cell C3. The fourth electrode pad 144 may overlap second electrodes 134 of the first light emitting cell C1, the second light emitting cell C2, and the third light emitting cell C3. The fourth electrode pad 144 may have a form different from those of the first electrode pad 141, the second electrode pad 142, and the third electrode pad 143. The first electrode pad 141, the second electrode pad 142, and the third electrode pad 143 may have a quadrangular shape. The fourth electrode pad 144 may have a bent form. The fourth electrode pad 144 may be used as a common terminal of the first light emitting cell C1, the second light emitting cell C2, and the third light emitting cell C3.

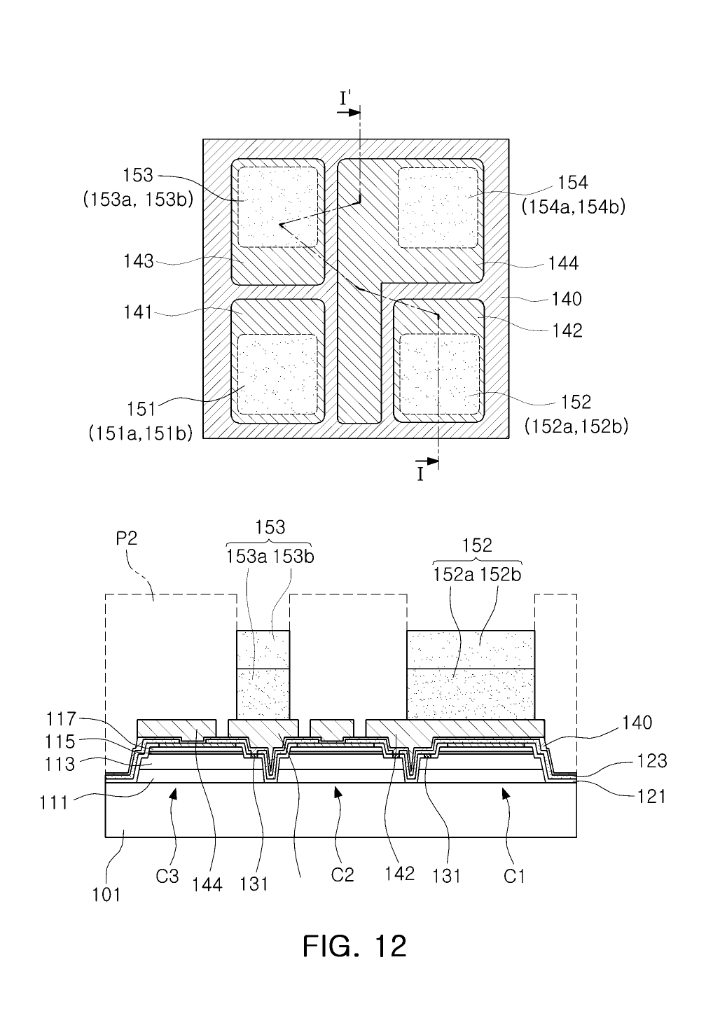

With reference to FIG. 12, a first metal pillar 151, a second metal pillar 152, a third metal pillar 153, and a fourth metal pillar 154 may be formed on the first electrode pad 141, the second electrode pad 142, the third electrode pad 143, and the fourth electrode pad 144, respectively.

After a second photoresist pattern P2 is formed, the first metal pillar 151, the second metal pillar 152, the third metal pillar 153, and the fourth metal pillar 154 may be formed using the plating process. The second photoresist pattern P2 may be removed after the plating process is completed.

The first metal pillar 151 formed on the first electrode pad 141 may include a first conductive layer 151a and a first bonding layer 151b. The second metal pillar 152 formed on the second electrode pad 142 may include a second conductive layer 152a and a second bonding layer 152b. The third metal pillar 153 formed on the third electrode pad 143 may include a third conductive layer 153a and a third bonding layer 153b. The fourth metal pillar 154 formed on the fourth electrode pad 144 may include a fourth conductive layer 154a and a fourth bonding layer 154b. The fourth metal pillar 154 may be used as a common terminal of the first light emitting cell C1, the second light emitting cell C2, and the third light emitting cell C3 in the same manner as the fourth electrode pad 144.

The first conductive layer 151a, the second conductive layer 152a, the third conductive layer 153a, and the fourth conductive layer 154a may be formed of, for example, Cu. The first bonding layer 151b, the second bonding layer 152b, the third bonding layer 153b, and the fourth bonding layer 154b may be formed of, for example, AgSn alloy, Sn, SnAgCu alloy, or the like.

The first metal pillar 151, the second metal pillar 152, the third metal pillar 153, and the fourth metal pillar 154 may be formed, for example, to have a thickness of about 70 μm. The first conductive layer 151a, the second conductive layer 152a, the third conductive layer 153a, and the fourth conductive layer 154a may be formed, for example, to have a thickness of about 40 μm, while the first bonding layer 151b, the second bonding layer 152b, the third bonding layer 153b, and the fourth bonding layer 154b may be formed, for example, to have a thickness of about 30 μm.

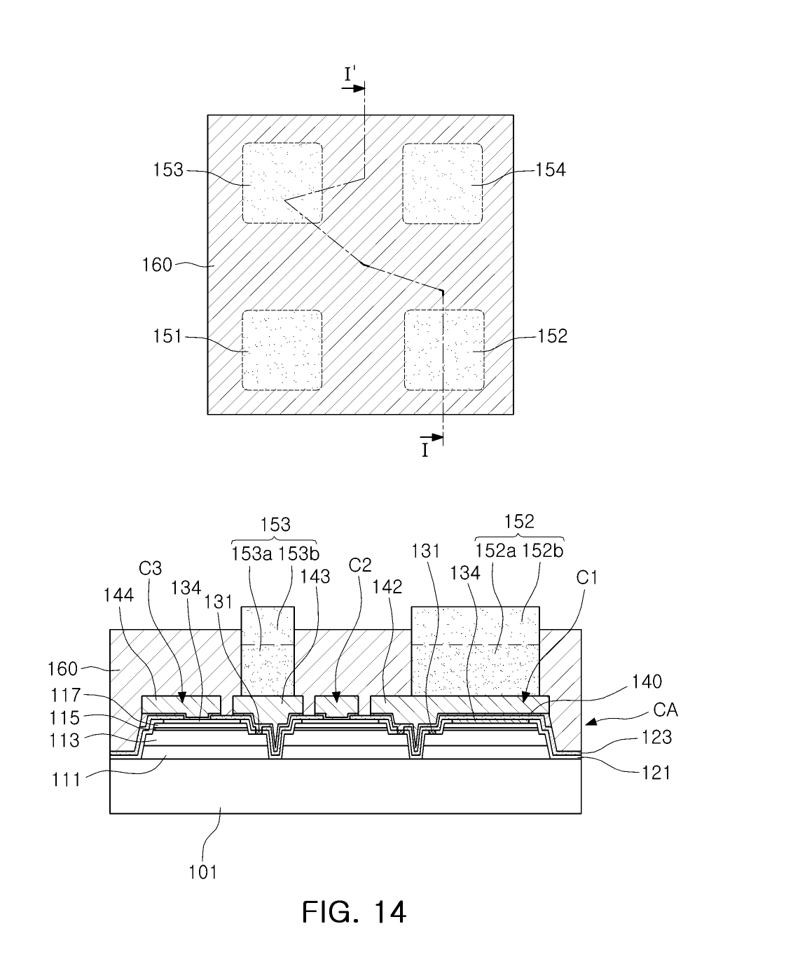

In the embodiment of FIG. 5, in which the first bonding layer 151b″, the second bonding layer 152b″, the third bonding layer 153b″, and the fourth bonding layer 154b″ have wider widths than the first conductive layer 151a, the second conductive layer 152a, the third conductive layer 153a, and the fourth conductive layer 154a, respectively, only the first conductive layer 151a, the second conductive layer 152a, the third conductive layer 153a, and the fourth conductive layer 154a may be formed at this point in the process. For example, the second photoresist pattern P2 may be provided and the first conductive layer 151a, the second conductive layer 152a, the third conductive layer 153a, and the fourth conductive layer 154a may be formed using the plating process. The second photoresist pattern P2 may be removed after the plating process is completed. Then, as discussed further below in connection with FIG. 14, molding portion 160 may be deposited to cover the first electrode pad 141, the second electrode pad 142, the third electrode pad 143, and the fourth electrode pad 144, as well as the first conductive layer 151a, the second conductive layer 152a, the third conductive layer 153a, and the fourth conductive layer 154a. After deposition, the molding portion 160 may be subject to a polishing process, such as grinding, to expose top surfaces of the first conductive layer 151a, the second conductive layer 152a, the third conductive layer 153a, and the fourth conductive layer 154a. Then a third photoresist pattern (not illustrated) may be provided, the third photoresist pattern being narrower than the second photoresist pattern P2, and the first bonding layer 151b″, the second bonding layer 152b″, the third bonding layer 153b″, and the fourth bonding layer 154b″ may be formed using the plating process. The third photoresist pattern may then be removed. Optionally, in some embodiments, a second molding portion (not illustrated) may be provided to cover the molding portion 160, the first bonding layer 151b″, the second bonding layer 152b″, the third bonding layer 153b″, and the fourth bonding layer 154b″. In such embodiments, a portion of the second molding portion (not illustrated) may be removed using an etchback process so that one or more of the first bonding layer 151b″, the second bonding layer 152b″, the third bonding layer 153b″, and the fourth bonding layer 154b″ may be exposed.

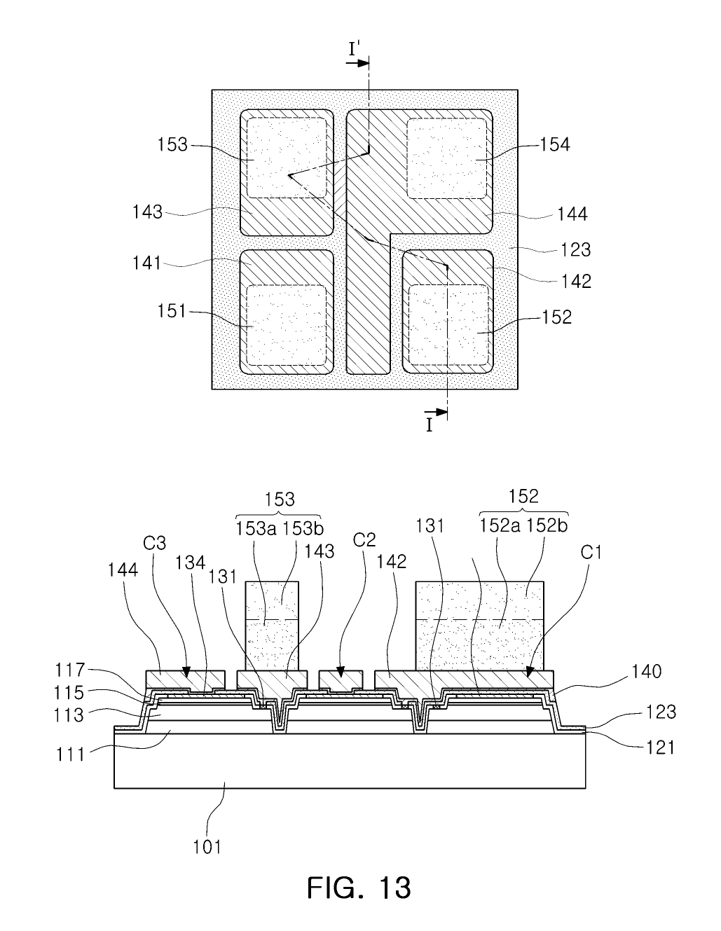

With reference to FIG. 13, portions of the seed metal layer 140 may be removed to expose the second insulating layer 123. Thus, the first electrode pad 141, the second electrode pad 142, the third electrode pad 143, and the fourth electrode pad 144 may be electrically isolated from each other. The first electrode pad 141 may be electrically connected to the first electrode 131 of the first light emitting cell C1, the second electrode pad 142 may be electrically connected to the first electrode 131 of the second light emitting cell C2, and the third electrode pad 143 may be electrically connected to the first electrode 131 of the third light emitting cell C3. The fourth electrode pad 144 may be electrically connected to the second electrodes 134 of the first light emitting cell C1, the second light emitting cell C2, and the third light emitting cell C3.

With reference to FIG. 14, a molding portion 160 covering the first electrode pad 141, the second electrode pad 142, the third electrode pad 143, and the fourth electrode pad 144, as well as the first metal pillar 151, the second metal pillar 152, the third metal pillar 153, and the fourth metal pillar 154 may be formed.

A process of forming the molding portion 160 may include a process of coating a molding material to cover the first electrode pad 141, the second electrode pad 142, the third electrode pad 143, and the fourth electrode pad 144, as well as the first metal pillar 151, the second metal pillar 152, the third metal pillar 153, and the fourth metal pillar 154 and may include a polishing process, such as grinding, exposing end portions of the first metal pillar 151, the second metal pillar 152, the third metal pillar 153, and the fourth metal pillar 154.

Since the molding portion 160 should be able to support a light emitting structure, the molding portion 160 should have a high Young's modulus. In addition, a material having relatively high thermal conductivity may be used to emit heat generated in the light emitting structure. The molding portion 160 may include, for example, an epoxy resin or a silicone resin. The molding portion 160 may include light reflective particles to reflect light. Titanium dioxide (TiO₂) and/or aluminum oxide (A1₂O₃) may be used as the light reflective particles, but the disclosure is not limited thereto.

Subsequently, a portion of the molding portion 160 may be removed using an etchback process so that one or more of the first metal pillar 151, the second metal pillar 152, the third metal pillar 153, and the fourth metal pillar 154 may be exposed. A portion of the first bonding layer 151b, the second bonding layer 152b, the third bonding layer 153b, and the fourth bonding layer 154b of the first metal pillar 151, the second metal pillar 152, the third metal pillar 153, and the fourth metal pillar 154 may be exposed. An upper surface of the molding portion 160 may be lower than upper surfaces of the first bonding layer 151b, the second bonding layer 152b, the third bonding layer 153b, and the fourth bonding layer 154b, and may be higher than upper surfaces of the first conductive layer 151a, the second conductive layer 152a, a third conductive layer 153a, and a fourth conductive layer 154a. The molding portion 160 may not expose the first conductive layer 151a, the second conductive layer 152a, the third conductive layer 153a, and the fourth conductive layer 154a.

With reference to FIG. 15, regions of the growth substrate 101 corresponding to the first light emitting cell C1, the second light emitting cell C2, and the third light emitting cell C3 may be etched, thereby forming a partition structure 165 including a first light emitting window W1, a second light emitting window W2, and a third light emitting window W3. In some embodiments, a portion thereof may be removed using a grinding process before the growth substrate 101 is etched.

With reference to FIG. 16, a light transmissive liquid resin mixed with a wavelength converting material, such as a green phosphor, may be dispensed to the first light emitting window W1, thereby forming a first phosphor layer 171a. A light transmissive liquid resin mixed with a wavelength converting material, such as a red phosphor, may be dispensed to the third light emitting window W3, thereby forming a third phosphor layer 173a.

In addition, a light transmissive liquid resin mixed with a blue phosphor or a cyan phosphor of a wavelength (e.g., a wavelength of 480 μm to 520 μm) different from that of blue light emitted by an active layer 115 may be dispensed to the second light emitting window W2, thereby forming a second phosphor layer 172a. According to an example embodiment, only a light transmissive liquid resin not mixed with a phosphor may be dispensed to the second light emitting window W2.

In some embodiments, a first optical filter layer 171c and a third optical filter layer 173c, selectively blocking light emitted by the active layer 115, may be formed in the first light emitting window W1 and the third light emitting window W3, respectively.

With reference to FIG. 3, a transparent resin layer may be coated to cover an upper end of the partition structure 165, and then, the partition structure 165 and the transparent resin layer may be polished to have a predetermined height. The transparent resin layer may form transparent resin layers 171b, 172b, and 173b. For example, the transparent resin layer may include an epoxy resin or a silicone resin. Subsequently, color filter layers 181 and 183 may be formed in the first light emitting window W1 and the third light emitting window W3, respectively. In some embodiments, the transparent resin layer may be further coated using a spin coating method.

Subsequently, a chip scale light emitting device package 10 may be manufactured in such a manner that a wafer level package manufactured using a manufacturing process described above is cut into individual package units.

A method of manufacturing a light emitting device package described above relates to a method of manufacturing a wafer level chip scale package. A chip scale package may substantially have a package size equal to that of the semiconductor light emitting device. Thus, in a case in which the chip scale package is used in a display panel, a high-resolution display panel may be manufactured by reducing a pixel size and a pixel pitch. In addition, since all processes are performed on a wafer level, the method of manufacturing a light emitting device package described above is suitable for mass production and has an advantage in which an optical structure, such as a light adjusting portion including a phosphor and a filter, together with light emitting cells may be integrally manufactured.

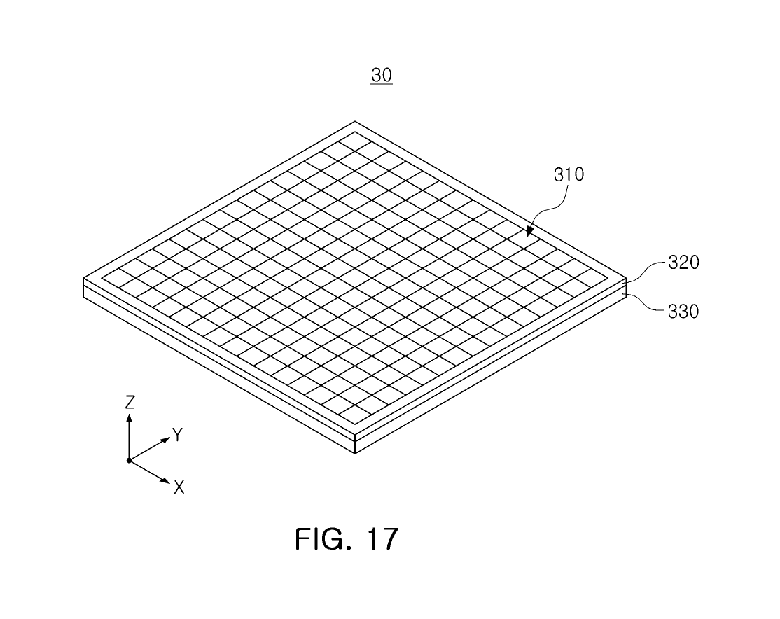

FIG. 17 is a schematic perspective view of a display panel including a light emitting device package according to an example embodiment.

With reference to FIG. 17, a display panel 30 may include a circuit board 330 and a light emitting device module 320 arranged on the circuit board 330.

The light emitting device module 320 according to an example embodiment may include a plurality of light emitting device packages 10 selectively emitting red light (R), green light (G), and blue light (B). Each of the plurality of light emitting device packages 10 may form a single pixel 310 of the display panel 30 and may be arranged on the circuit board 330 in rows and columns. In an example embodiment, a configuration in which light emitting device packages 10 are arranged to have a size of 15×15 is illustrated, for the sake of convenience of explanation. In actuality, a larger number of light emitting device packages (e.g., 1024×768, 1920×1080 or the like) may be arranged depending on required resolution.

The circuit board 330 may include a driving unit configured to supply power to each light emitting device package 10 of the light emitting device module 320 and a control unit controlling the light emitting device package 10. For example, each light emitting device package 10 may correspond to a single color pixel, and each of the first light emitting cell C1, the second light emitting cell C2, and the third light emitting cell C3 may be sub-pixels of the single color pixel. Each sub-pixel may be separately operable to emit a color of a pixel of an array of pixels of a display.

In some embodiments, the display panel 30 may further include a black matrix disposed on the circuit board 330 to define a region on which the light emitting device package 10 is mounted. The black matrix is not limited to black and may be changed to have another color, for example, a white matrix or a green matrix, depending on an application of a product. In some embodiments, a matrix formed of a transparent material may also be used. The white matrix may further include a reflective material or a light scattering material.

As set forth above, according to example embodiments, a chip-scale light emitting device package may include a bonding layer formed below a metal pillar, thereby allowing for ease in a process in which the light emitting device package is mounted on a circuit board, while a separate solder printing process may not be performed, and a difference in heights of bumps on a wafer level may be minimized, thereby allowing the light emitting device package to be mounted without a problem in which the light emitting device package is twisted.

While example embodiments have been shown and described above, it will be apparent to those skilled in the art that modifications and variations could be made without departing from the scope of the present inventive concept as defined by the appended claims.

What is claimed is:

1. A light emitting device package, comprising:
a light emitting cell array having a first surface and a second surface that is opposite to the first surface, the light emitting cell array including a first light emitting cell, a second light emitting cell, and a third light emitting cell, wherein each of the first light emitting cell, the second light emitting cell, and the third light emitting cell has a first conductivity-type semiconductor layer, an active layer, and a second conductivity-type semiconductor layer;
a plurality of metal pillars disposed on the first surface of the light emitting cell array and electrically connected to the first light emitting cell, the second light emitting cell, and the third light emitting cell; and
a molding portion encapsulating the light emitting cell array and the plurality of metal pillars,
wherein each of the plurality of metal pillars includes a conductive layer and a bonding layer, the conductive layer being disposed between the light emitting cell array and the bonding layer, and
wherein an interface between the bonding layer and the conductive layer is at a higher vertical level than a lower surface of the molding portion.

2. The light emitting device package of claim 1, wherein a lower surface of the bonding layer is at a lower vertical level than the lower surface of the molding portion.

3. The light emitting device package of claim 1, wherein at least a side surface of the bonding layer is coplanar with a side surface of the conductive layer.

4. The light emitting device package of claim 1, wherein a thickness in a vertical direction of the bonding layer is less than a thickness in the vertical direction of the conductive layer.

5. The light emitting device package of claim 1, wherein the bonding layer includes a first region having a side surface in contact with the molding portion and a second region having a convex curved surface.

6. The light emitting device package of claim 1, wherein a width in a horizontal direction of the bonding layer is greater than a width in the horizontal direction of the conductive layer.

7. The light emitting device package of claim 1, wherein the plurality of metal pillars include a first metal pillar electrically connected to the first light emitting cell, a second metal pillar electrically connected to the second light emitting cell, a third metal pillar electrically connected to the third light emitting cell, and a fourth metal pillar electrically connected in common to the first light emitting cell, the second light emitting cell, and the third light emitting cell.

8. The light emitting device package of claim 7, further comprising:
a first electrode pad connecting the first metal pillar to the first light emitting cell;
a second electrode pad connecting the second metal pillar to the second light emitting cell;
a third electrode pad connecting the third metal pillar to the third light emitting cell; and
a fourth electrode pad connecting the fourth metal pillar to the first light emitting cell, the second light emitting cell, and the third light emitting cell.

9. The light emitting device package of claim 8, wherein a form of the fourth electrode pad is different from forms of the first electrode pad, the second electrode pad, and the third electrode pad.

10. The light emitting device package of claim 1, further comprising:
a partition structure disposed on the second surface of the light emitting cell array and including a first light emitting window, a second light emitting window, and a third light emitting window respectively corresponding to the first light emitting cell, the second light emitting cell, and the third light emitting cell, respectively; and
a first light adjusting portion, a second light adjusting portion, and a third light adjusting portion respectively disposed on a first light emitting window, a second light emitting window, and a third light emitting window and configured to provide red light, blue light, and green light, respectively.

11. The light emitting device package of claim 10, further comprising:
an insulating layer covering a side surface of the first light emitting cell, the second light emitting cell, and the third light emitting cell, the insulating layer being in contact with the partition structure.

12. The light emitting device package of claim 10, wherein the partition structure is formed of single crystal silicon (Si).

13. A light emitting device package, comprising:
a light emitting cell array having a first surface and a second surface opposite the first surface, the light emitting cell array including a plurality of light emitting cells;
a plurality of metal pillars disposed on the first surface of the light emitting cell array and electrically connected to the plurality of light emitting cells, one of the plurality of metal pillars being electrically connected in common to the plurality of light emitting cells; and
a molding portion encapsulating the light emitting cell array and the plurality of metal pillars,
wherein each of the plurality of metal pillars includes at least two layers stacked on one another, each of the at least two layers being comprised of a different material, and
wherein a lower surface of the plurality of metal pillars protrudes beyond a lower surface of the molding portion.

14. The light emitting device package of claim 13, wherein the at least two layers of each of the plurality of metal pillars includes a conductive layer and a bonding layer, the conductive layer being disposed between the light emitting cell array and the bonding layer, and
wherein an interface between the bonding layer and the conductive layer is at a higher vertical level than the lower surface of the molding portion.

15. The light emitting device package of claim 14, wherein a lower surface of the bonding layer is at a lower vertical level than the lower surface of the molding portion.

16. The light emitting device package of claim 14, wherein a thickness of the bonding layer is less than a thickness of the conductive layer, and
wherein the bonding layer includes a first region having a side surface in contact with the molding portion and a second region having a convex curved surface.

17. The light emitting device package of claim 13, further comprising:
a plurality of electrode pads connected to the plurality of metal pillars, respectively, wherein a form of one of the plurality of electrode pads is different from a form of the remainder.

18. The light emitting device package of claim 13, further comprising:
a plurality of light adjusting portions configured to adjust light emitted by the plurality of light emitting cells to provide red light, blue light, and green light, respectively.

19. A light emitting device package, comprising:
a light emitting cell array having a first surface, and a second surface, disposed opposite the first surface, the light emitting cell array including a first light emitting cell, a second light emitting cell, and a third light emitting cell, each of the first light emitting cell, the second light emitting cell, and the third light emitting cell having a first conductivity-type semiconductor layer, an active layer, and a second conductivity-type semiconductor layer;
four metal pillars disposed on the first surface of the light emitting cell array and electrically connected to the first light emitting cell, the second light emitting cell, and the third light emitting cell;
a partition structure disposed on the second surface of the light emitting cell array and including a first light emitting window, a second light emitting window, and a third light emitting window, wherein the first light emitting window, the second light emitting window, and the third light emitting window corresponding to the first light emitting cell, the second light emitting cell, and the third light emitting cell, respectively;
a first light adjusting portion, a second light adjusting portion, and a third light adjusting portion respectively disposed in the first light emitting window, the second light emitting window, and the third light emitting window and respectively configured to provide red light, blue light, and green light; and
a molding portion encapsulating the light emitting cell array and the four metal pillars,
wherein lower surfaces of the four metal pillars protrude beyond a lower surface of the molding portion,
wherein each of the four metal pillars includes a conductive layer and a bonding layer, the conductive layer and the bonding layer being formed of different materials, and
wherein an interface between the bonding layer and the conductive layer is at a higher vertical level than the lower surface of the molding portion.

20. The light emitting device package of claim 19, wherein a side surface of the bonding layer is coplanar with a side surface of the conductive layer.
